(19) United States
(12) Patent Application Publication
(10) Pub. No.: US 2010/0133094 A1
(43) Pub. Date: Jun. 3, 2010

(54) TRANSPARENT CONDUCTIVE FILM WITH HIGH TRANSMITTANCE FORMED BY A REACTIVE SPUTTER DEPOSITION

(75) Inventors: Hien-Minh Huu Le, San Jose, CA (US); David Tanner, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/326,571

(22) Filed: Dec. 2, 2008

(51) Int. Cl. C23C 14/34

(52) U.S. Cl. 204/192.29

(57) ABSTRACT

Methods for sputter depositing a transparent conductive layer are provided in the present invention. The transparent conductive layer may be utilized as a contact layer on a substrate or a back reflector in a photovoltaic device. In one embodiment, the method includes supplying a gas mixture into the processing chamber, sputtering source material from a target disposed in the processing chamber, wherein the target is fabricated from a zinc containing material having an aluminum containing dopant concentration less than 3 percent by weight, and reacting the sputtered material with the gas mixture.

### BACKGROUND OF THE DISCLOSURE

1. Field of the Invention

The present invention relates to methods and apparatus for depositing a transparent conductive film, more specifically, for reactively sputter depositing a transparent conductive film with high transmittance suitable for photovoltaic devices.

2. Description of the Background Art

Photovoltaic (PV) devices or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are created by connecting a number of PV solar cells and are then joined into panels with frames and connectors.

Several types of silicon films, including microcrystalline silicon film (μc-Si), amorphous silicon film (a-Si), polycrystalline silicon film (poly-Si) and the like, may be utilized to form PV devices. A transparent conductive film or a transparent conductive film may be used as a top surface electrode, often referred as back reflector, disposed on the top of the PV solar cells. Furthermore, the TCO layer may be disposed between a substrate and a photoelectric conversion unit as a contact layer. The transparent conductive film must have high optical transmittance in the visible or higher wavelength region to facilitate transmitting sunlight into the solar cells without adversely absorbing or reflecting light energy. Additionally, low contact resistance and high electrical conductivity of the transparent conductive film are desired to provide high photoelectric conversion efficiency and electricity collection. Certain degree of texture or surface roughness of the transparent conductive layer is also desired to assist sunlight trapping in the films by promoting light scattering. Overly high impurities or contaminant of the transparent conductive film often result in high contact resistance at the interface of the transparent conductive film and adjacent films, thereby reducing carrier mobility within the PV cells. Furthermore, insufficient transparency of the transparent conductive film may adversely reflect light back to the environment, resulting in a diminished amount of sunlight entering the PV cells and a reduction in the photoelectric conversion efficiency.

Therefore, there is a need for an improved method for depositing a transparent conductive film for PV cells.

### SUMMARY OF THE INVENTION

Methods for sputter deposition of a transparent conductive layer suitable with high transmittance for use in PV cells are provided. A physical vapor deposition (e.g., a sputter deposition) process is utilized to deposit the high transmittance TCO layer. In one embodiment, a method for sputter deposition of a transparent conductive layer includes supplying a gas mixture into the processing chamber, sputtering source material from a target disposed in the processing chamber, wherein the target is fabricated from a zinc containing material having an aluminum containing dopant concentration less than 3 percent by weight, and reacting the sputtered material with the gas mixture.

In another embodiment, a method for sputter deposition of a transparent conductive layer includes providing a substrate in a processing chamber, supplying a gas mixture into the processing chamber, sputtering source material from a target disposed in the processing chamber, reacting the sputtered material with the gas mixture, and forming a transparent conductive layer on the substrate, wherein the transparent conductive layer is a zinc oxide layer having an aluminum oxide dopant concentration between about 0.25 percent by weight and about 3 percent by weight.

In yet another embodiment, a method for sputter deposition of a transparent conductive layer includes providing a substrate in a processing chamber, supplying a gas mixture comprising at least an argon gas and an oxygen gas into the processing chamber, sputtering source material from a target fabricated from a zinc oxide material having an aluminum oxide dopant concentration less than 3 percent by weight disposed in the processing chamber, and reacting the sputtered source material with the gas mixture to form a transparent conductive layer on the substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view of one embodiment of a process chamber in accordance with the invention;

FIG. 2 depicts an exemplary cross sectional view of a crystalline silicon-based thin film PV solar cell in accordance with one embodiment of the present invention;

FIG. 3 depicts a process flow diagram of manufacturing a TCO layer in accordance with one embodiment of the present invention; and

FIG. 4 depicts an exemplary cross sectional view of a tandem type PV solar cell in accordance with one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides methods for sputter depositing a transparent conductive layer, such as a transparent conductive oxide layer (TCO layer) suitable with high transmittance for use in the fabrication of solar cells. In one embodiment, the TCO layer is sputter deposited by supplying different gas mixtures along with different target material selections to deposit a TCO layer having a desired dopant concentration formed therein.

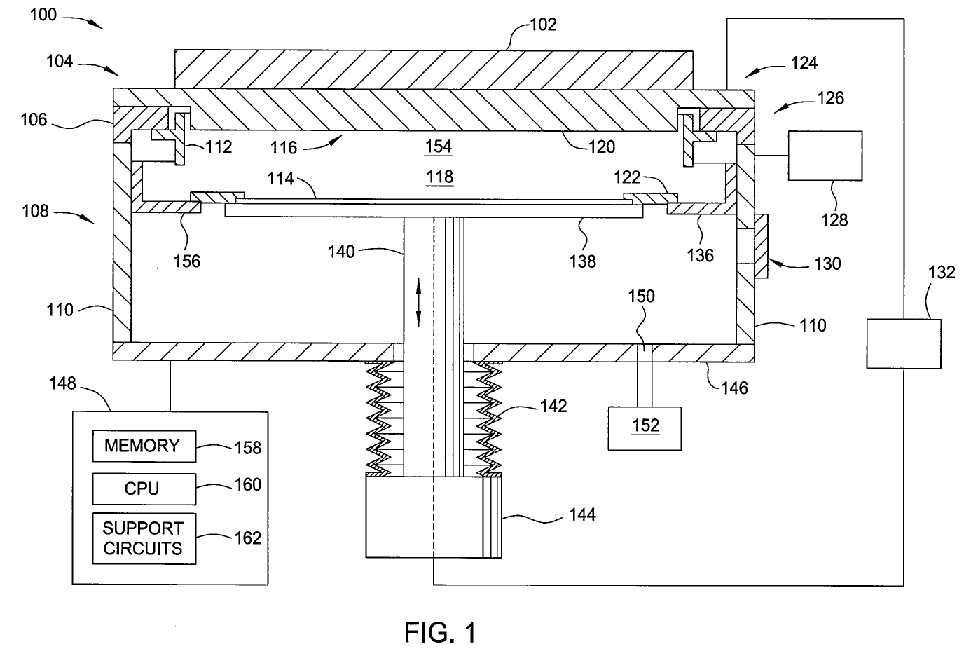

FIG. 1 illustrates an exemplary reactive sputter process chamber 100 suitable for sputter depositing materials according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufactures, may be adapted to practice the present invention.

The process chamber 100 includes a chamber body 108 having a processing volume 118 defined therein. The chamber body 108 has sidewalls 110 and a bottom 146. The dimensions of the chamber body 108 and related components of the process chamber 100 are not limited and generally are proportionally larger than the size of the substrate 114 to be processed. Any substrate size may be processed in a suitably configured chamber. Examples of suitable substrate sizes include substrate having a surface area of about 2,000 centimeter square or more, such as about 4,000 centimeter square or more, for example about 10,000 centimeter square or more. In one embodiment, a substrate having a surface area of about 50,000 centimeter square or more or more may be processed.

A chamber lid assembly 104 is mounted on the top of the chamber body 108. The chamber body 108 may be fabricated from aluminum or other suitable materials. A substrate access port 130 is formed through the sidewall 110 of the chamber body 108, facilitating the transfer of a substrate 114 (i.e., a solar panel, a flat panel display substrate, a semiconductor wafer, or other workpiece) into and out of the process chamber 100. The access port 130 may be coupled to a transfer chamber and/or other chambers of a substrate processing system.

A gas source 128 is coupled to the chamber body 108 to supply process gases into the processing volume 118. In one embodiment, process gases may include inert gases, non-reactive gases, and reactive gases. Examples of process gases that may be provided by the gas source 128 include, but not limited to, argon gas (Ar), helium (He), nitrogen gas (N₂), oxygen gas (O₂), H₂, NO₂, N₂O and H₂O among others.

A pumping port 150 is formed through the bottom 146 of the chamber body 108. A pumping device 152 is coupled to the process volume 118 to evacuate and control the pressure therein. In one embodiment, the pressure level of the process chamber 100 may be maintained at about 1 Torr or less. In another embodiment, the pressure level of the process chamber 100 may be maintained at about 10⁻³Torr or less. In yet another embodiment, the pressure level of the process chamber 100 may be maintained at about 10⁻⁵ Torr to about 10⁻⁷ Torr. In another embodiment, the pressure level of the process chamber 100 may be maintained at about 10⁻⁷ Torr or less.

The lid assembly 104 generally includes a target 120 and a ground shield assembly 126 coupled thereto. The target 120 provides a material source that can be sputtered and deposited onto the surface of the substrate 114 during a PVD process. The target 120 or target plate may be fabricated from a material utilized for deposition species. A high voltage power supply, such as a power source 132, is connected to the target 120 to facilitate sputtering materials from the target 120. In one embodiment, the target 120 may be fabricated from a material containing zinc (Zn) metal. In another embodiment, the target 120 may be fabricated from materials including metallic zinc (Zn) containing target, zinc alloy, zinc and aluminum alloy and the like. In yet another embodiment, the target 120 may be fabricated from materials including a zinc containing material and an aluminum containing material. In one embodiment, the target may be fabricated from a zinc oxide and aluminum oxide material.

In one embodiment, the target 120 is fabricated from a zinc and aluminum alloy having a desired ratio of zinc element to aluminum element fabricated in the target 120. The aluminum elements formed in the target 120 assists maintaining the target conductivity at a certain range so as to efficiently enable a uniform sputter process across the target surface. The aluminum elements in the target 120 is also believed to increase film transmittance when sputtered off and deposited onto the substrate. In one embodiment, the concentration of the aluminum element formed in the zinc target 120 is controlled at less than about 5 percent by weight. In the embodiment wherein the target 120 is fabricated from ZnO and Al₂O₃ alloy, the Al₂O₃ dopant concentration in the ZnO target is controlled at less than about 3 percent by weight, for example about less than 2 percent by weight, such as about less than 0.5 percent by weight, for example, about 0.25 percent by weight.

The target 120 generally includes a peripheral portion 124 and a central portion 116. The peripheral portion 124 is disposed over the sidewalls 110 of the chamber 100. The central portion 116 of the target 120 may have a curvature surface slightly extending towards the surface of the substrate 114 disposed on a substrate support 138. The spacing between the target 120 and the substrate support 138 is maintained between about 50 mm and about 150 mm during processing. It is noted that the dimension, shape, materials, configuration and diameter of the target 120 may be varied for specific process or substrate requirements. In one embodiment, the target 120 may further include a backing plate having a central portion bonded and/or fabricated from a material desired to be sputtered onto the substrate surface. The target 120 may also include adjacent tiles or material segments that together forming the target.

Optionally, the lid assembly 104 may further comprise a magnetron assembly 102 mounted above the target 120 which enhances efficient sputtering materials from the target 120 during processing. Examples of the magnetron assembly 102 include a linear magnetron, a serpentine magnetron, a spiral magnetron, a double-digitated magnetron, a rectangularized spiral magnetron, among others.

The ground shield assembly 126 of the lid assembly 104 includes a ground frame 106 and a ground shield 112. The ground shield assembly 126 may also include other chamber shield member, target shield member, dark space shield, dark space shield frame. The ground shield 112 is coupled to the peripheral portion 124 by the ground frame 106 defining an upper processing region 154 below the central portion of the target 120 in the process volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source to be mainly deposited on the substrate surface rather than chamber sidewalls 110. In one embodiment, the ground shield 112 may be formed by one or more work-piece fragments and/or a number of these pieces bonding by a substrate process, such as welding, gluing, high pressure compression, etc.

A shaft 140 extending through the bottom 146 of the chamber body 108 couples to a lift mechanism 144. The lift mechanism 144 is configured to move the substrate support 138 between a lower transfer position and an upper processing position. A bellows 142 circumscribes the shaft 140 and coupled to the substrate support 138 to provide a flexible seal therebetween, thereby maintaining vacuum integrity of the chamber processing volume 118.

A shadow frame 122 is disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing, an outer edge of the substrate 114 disposed on the substrate support 138 is engaged by the shadow frame 122 and the shadow frame 122 is lifted up and spaced away from the chamber shield 136. When the substrate support 138 is lowered to the transfer position adjacent to the substrate transfer port 130, the shadow frame 122 is set back on the chamber shield 136. Lift pins (not shown) are selectively moved through the substrate support 138 to list the substrate 114 above the substrate support 138 to facilitate access to the substrate 114 by a transfer robot or other suitable transfer mechanism.

A controller 148 is coupled to the process chamber 100. The controller 148 includes a central processing unit (CPU) 160, a memory 158, and support circuits 162. The controller 148 is utilized to control the process sequence, regulating the gas flows from the gas source 128 into the chamber 100 and controlling ion bombardment of the target 120. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100 such that the processes are performed in accordance with the present invention. The software routines may also be stored and/or executed by a second controller (not shown) that is located remotely from the chamber 100.

During processing, the material is sputtered from the target 120 and deposited on the surface of the substrate 114. The target 120 and the substrate support 138 are biased relative to each other by the power source 132 to maintain a plasma formed from the process gases supplied by the gas source 128. The ions from the plasma are accelerated toward and strike the target 120, causing target material to be dislodged from the target 120. The dislodged target material and process gases forms a layer on the substrate 114 with desired compositions.

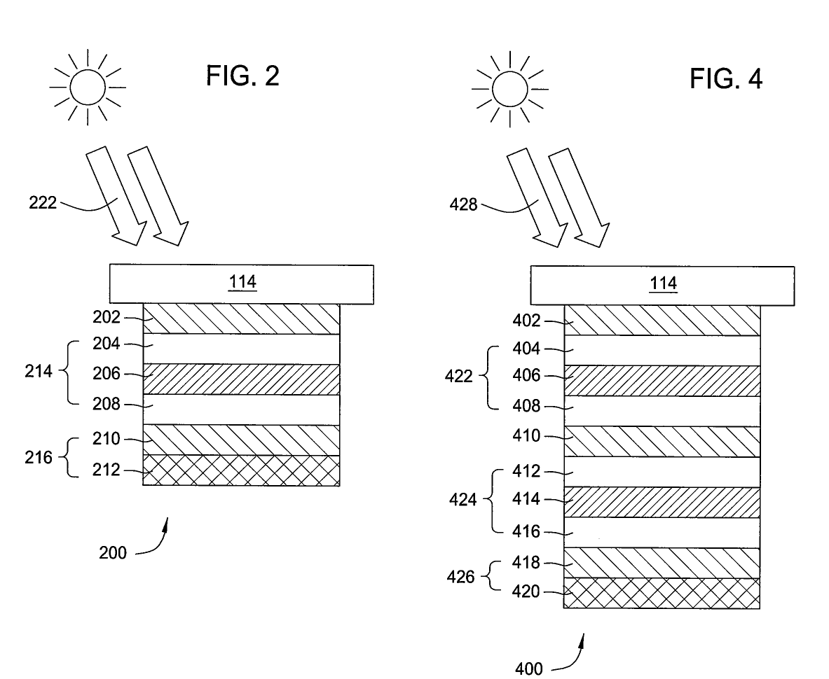

FIG. 2 depicts an exemplary cross sectional view of an amorphous silicon-based thin film PV solar cell 200 in accordance with one embodiment of the present invention. The amorphous silicon-based thin film PV solar cell 200 includes a substrate, such as the substrate 114 processed in the process chamber 100 of FIG. 1. The substrate 114 may be thin sheet of metal, plastic, organic material, silicon, glass, quartz, or polymer, or other suitable material. The substrate 114 may have a surface area greater than about 1 square meters, such as greater than about 2 square meters. Alternatively, the thin film PV solar cell 200 may also be fabricated as crystalline, microcrystalline or other type of silicon-based thin films as needed.

A photoelectric conversion unit 214 is formed on a transparent conductive layer, such as a TCO layer 202, disposed on the substrate 114. The photoelectric conversion unit 214 includes a p-type semiconductor layer 204, a n-type semiconductor layer 208, and an intrinsic type (i-type) semiconductor layer 206 sandwiched therebetween as a photoelectric conversion layer. An optional dielectric layer (not shown) may be disposed between the substrate 114 and the TCO layer 202, between the TCO layer 202 and the p-type semiconductor layer, or between the intrinsic type (i-type) semiconductor layer 206 and the n-type semiconductor layer 208 as needed. In one embodiment, the optional dielectric layer may be a silicon layer including amorphous or polysilicon, SiON, SiN, SiC, SiOC, silicon oxide (SiO₂) layer, doped silicon layer, or any suitable silicon containing layer.

The p-type and n-type semiconductor layers 204, 208 may be silicon based materials doped by an element selected either from group III or V. A group III element doped silicon film is referred to as a p-type silicon film, while a group V element doped silicon film is referred to as a n-type silicon film. In one embodiment, the n-type semiconductor layer 208 may be a phosphorus doped silicon film and the p-type semiconductor layer 204 may be a boron doped silicon film. The doped silicon films 204, 208 include an amorphous silicon film (a-Si), a polycrystalline film (poly-Si), and a microcrystalline film (μc-Si) with a total thickness between around 5 nm and about 50 nm. Alternatively, the doped element in semiconductor layers 204, 208 may be selected to meet device requirements of the PV solar cell 200. The n-type and p-type semiconductor layers 204, 208 may be deposited by a CVD process or other suitable deposition process.

The i-type semiconductor layer 206 is a non-doped type silicon based film. The i-type semiconductor layer 206 may be deposited under process condition controlled to provide film properties having improved photoelectric conversion efficiency. In one embodiment, the i-type semiconductor layer 206 may be fabricated from i-type polycrystalline silicon (poly-Si), i-type microcrystalline silicon film (μc-Si), amorphous silicon (a-Si), or hydrogenated amorphous silicon (a-Si).

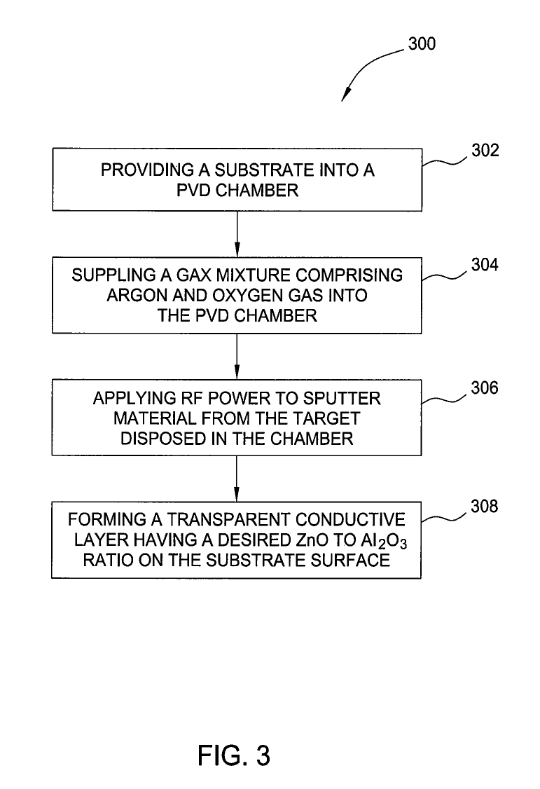

After the photoelectric conversion unit 214 is formed on the TCO layer 202, a back reflector 216 is formed on the photoelectric conversion unit 214. In one embodiment, the back reflector 216 may be formed by a stacked film that includes a transparent conductive layer, such as a transmitting conducting oxide (TCO) layer 210, and a conductive layer 212. The conductive layer 212 may be at least one of Ti, Cr, Al, Ag, Au, Cu, Pt, or their alloys. The transmitting conducting oxide (TCO) layer 210 may be fabricated from a material similar to the TCO layer 202 formed on the substrate 114. The transmitting conducting oxide (TCO) layers 202, 210 may be fabricated from a selected group consisting of tin oxide (SnO₂), indium tin oxide (ITO), zinc oxide (ZnO), or combinations thereof. In one exemplary embodiment, the transmitting conducting oxide (TCO) layers 202, 210 may be fabricated from a ZnO layer having a desired Al₂O₃ dopant concentration formed in the ZnO layer. Embodiments of a process 300 for forming a ZnO/Al₂O₃ layer are described below with reference to FIG. 3.

In embodiments depicted in FIG. 2, at least one of the transmitting conducting oxide (TCO) layers 202, 210 is fabricated by reactive sputter deposition process of the present invention. The sputter deposition process of TCO layers 202, 210 may be performed in the processing chamber 100, as described in FIG. 1.

FIG. 3 depicts a flow diagram of one embodiment of a sputtering deposition process 300 for depositing a transparent conductive layer, such as TCO layers 202, 210, on the substrate 114 or on the photoelectric conversion unit 214. The process 300 may be stored in the memory 158 as instructions that when executed by the controller 148, cause the process 300 to be performed in the process chamber 100. In embodiment depicted in FIG. 3, the process 300 may be performed in a Thin Film Solar PVD system from Applied Materials, Inc. It is contemplated that the method 300 may be performed in other systems, including those from other manufactures.

The process 300 begins at step 302 by providing a substrate into a sputter process chamber for deposition a transparent conductive layer on the substrate. In one embodiment, the transparent conductive layer is a TCO layer may be deposited as the TCO layer 202 on the substrate 114. In another embodiment, the TCO layer may be deposited as the TCO layer on the photoelectric conversion unit 214 as the back reflector 216.

At step 304, a process gas mixture is supplied into the sputter process chamber. The process gas mixture supplied in the sputter process chamber assists bombard the source material from the target 120 and reacts with the sputtered material to form the desired TCO layer on the substrate surface. In one embodiment, the gas mixture may include reactive gas, non-reactive gas, and the like. Examples of non-reactive gas include, but not limited to, inert gas, such as Ar, He, Xe, and Kr, or other suitable gases. Examples of reactive gas include, but not limited to, O₂, N₂, N₂O, NO₂, H₂, NH₃, H₂O, among others.

In one embodiment, the argon (Ar) gas supplied into the sputter process chamber assists bombarding the target to sputter materials from the target surface. The sputtered materials from the target react with the reactive gas in the sputter process chamber, thereby forming a TCO layer having desired film properties on the substrate. The TCO layer formed at different location of the photoelectric conversion unit may require different film properties to achieve different current conversion efficiency requirement. For example, the bottom TCO layer 202 may require film properties, such as relatively high textured surface, high transparency, and high conductivity. The upper TCO layer 210 may require high transparency as well, however, the requirement for surface texturing is much less than that of the bottom TCO layer 202. The gas mixture and/or other process parameters may be varied during the sputtering deposition process, thereby creating the TCO layer with desired film properties for different film quality requirements.

In one particular embodiment, the process gas mixture supplied into the sputter process chamber includes at least one of Ar, O₂ or H₂. In one embodiment, the O₂ gas may be supplied at a flow rate between about 0 sccm and about 100 sccm, such as between about 5 sccm and about 30 sccm, for example between about 5 sccm and about 15 sccm. The Ar gas may be supplied into the processing chamber 100 at a flow rate between about 150 sccm and between 500 sccm. The H₂ gas may be supplied into the processing chamber 100 at a flow rate between about 0 sccm and between 100 sccm, such as between about 5 sccm and about 30 sccm. Alternatively, O₂ gas flow may be controlled at a flow rate per total flow rate between about 1 percent and about 10 percent to the total gas flow rate. H₂ gas flow may be controlled at a flow rate per total flow rate between about 1 percent and about 10 percent to the total gas flow rate.

In the embodiment wherein the gas mixture supplied into the process chamber includes Ar and O₂ gas, the Ar gas flow rate supplied in the gas mixture is controlled at between about 90 percent by volume to 100 percent by volume and the oxygen gas flow rate is controlled about less than 10 percent by volume. In the embodiment wherein the gas mixture supplied into the process chamber include Ar, O₂ and H₂ gas, the Ar gas flow rate supplied in the gas mixture is controlled at between about 80 percent by volume to 100 percent by volume, the oxygen gas flow rate is controlled about less than 10 percent by volume, and the hydrogen gas flow rate is also controlled at about less than 10 percent by volume.

As different gas mixtures supplied into the process chamber may provide different source ions that may be react with the source material sputtered off the target, by supplying different gas species in the gas mixture, a control of the film properties of the TCO layer may be obtained. For example, a greater amount of oxygen gas supplied in the gas mixture may result in a TCO layer having a higher quality of oxygen elements formed in the resultant TCO layer. Accordingly, by controlling the amount of reactive gas along with different selection of targets used during sputtering, a TCO layer having tailored film properties may be obtained.

At step 306, RF power is supplied to the target 120 to sputter the source material from the target 120 which reacts with the gas mixture supplied at step 304. As a high voltage power is supplied to the zinc (Zn) and aluminum (Al) alloy target 120, the metal zinc and aluminum source material is sputtered from the target 120 in form of zinc and aluminum ions, such as Zn⁺, Zn²⁺ and/or Al³⁺. The bias power applied between the target 120 and the substrate support 138 maintains a plasma formed from the gas mixture in the process chamber 100. The ions mainly from the gas mixture in the plasma bombard and sputter off material from the target 120. The reactive gases react with the growing sputtered film to form a layer with desired composition on the substrate 114. In one embodiment, a metal alloy target made of Zinc (Zn) and aluminum (Al) metal alloy is utilized as a source material of the target 120 for sputter process. The ratio of Al metal included in the Zn target 120 is controlled at about less than 3 percent by weight, such as less than 2 percent by weight, such as about less than 0.5 percent by weight, for example, about 0.25 percent by weight. In another embodiment, a metal alloy target made of zinc oxide (ZnO) and aluminum oxide (Al₂O₃) metal alloy is utilized as a source material of the target 120 for sputter process. The ratio of Al₂O₃ included in the ZnO target 120 is controlled at between about less than 3 percent by weight, for example about less than 2 percent by weight, such as about less than 0.5 percent by weight, for example, about 0.25 percent by weight.

In the embodiment wherein the target is made of Zinc (Zn) and aluminum (Al) metals, the gas mixture supplied for sputtering may include argon and oxygen gas. The argon gas is used to bombard and sputter the target, and the oxygen ions dissociated from the O₂ gas mixture reacts with the zinc and aluminum ions sputtered from the target, forming a zinc oxide (ZnO) and aluminum oxide (Al₂O₃) containing TCO layer 202 or 210 on the substrate 114. The RF power is applied to the target 120 during processing. In the embodiment wherein the target 120 is fabricated from ZnO having Al₂O₃ doped therein, the gas mixture used to bombard the target may include argon but may or may not include O₂ gas. In this embodiment, the oxygen gas may be optionally eliminated as the target 120 provides the oxygen elements that are deposited in the TCO layer. In some embodiments, the hydrogen gas may be used in the gas mixture to assist bombard and react with the source material from the target 120 with regardless the materials of the target.

In one embodiment, a RF power of between about 100 Watts and about 60000 Watts may be supplied to the target. Alternatively, the RF power may be controlled by RF power density supplied between about 0.15 Watts per centimeter square and about 15 Watts per centimeter square, for example, about 4 Watts per centimeter square and about 8 Watts per centimeter square. Alternatively, the DC power may be supplied between about 0.15 Watts per centimeter square and about 15 Watts per centimeter square.

Several process parameters may be regulated at step 304 and 306. In one embodiment, a pressure of the gas mixture in the process chamber 100 is regulated between about 2 mTorr and about 10 mTorr. The substrate temperature may be maintained between about 25 degrees Celsius and about 100 degrees Celsius. The processing time may be processed at a predetermined processing period or after a desired thickness of the layer is deposited on the substrate. In one embodiment, the process time may be processed at between about 30 seconds and about 400 seconds. In one embodiment, the thickness of the TCO layer is between about 5000 Å and about 10,000 Å. In the embodiment wherein a substrate with different dimension is desired to be processed, process temperature, pressure and spacing configured in a process chamber with different dimension do not change in accordance with a change in substrate and/or chamber size.

At step 308, as the ions dissociated from the gas mixture react with sputtered off material from the target 120, a TCO layer with desired composition is therefore formed on the substrate surface. In one embodiment, the TCO layer as deposited is a ZnO layer having a desired amount of aluminum oxide dopant formed therein. It is believed that the TCO layer having a desired amount of Al₂O₃ dopant formed in the ZnO layer can efficiently improve current conversion efficiency of the photoelectric conversion unit. The aluminum elements formed in the TCO layer may provide higher film conductivity, thereby assisting carrying greater amount of current in the TCO layer. Additionally, it is believed that higher amount of oxygen elements formed in the TCO layer increases film transmittance that allows greater amount of current generated in the photoelectric conversion unit. Furthermore, a high film transparency is desired to maximize the light transmitting efficiency. Accordingly, by controlling a desired amount of aluminum oxide formed in the zinc containing layer, the TCO layer having desired film properties, such as high transmittance and high current conversion efficiency, may be obtained.

In one embodiment, the oxygen source formed in the TCO layer may be provided from the gas mixture supplied into the process chamber during sputter process. Alternatively, the oxygen source may be provided from a selected target having metal oxide alloy prefabricated in the target so that when sputtering, both metallic and oxygen ions may be sputtered off the target and deposited on the substrate surface. In the embodiment wherein the selected target 120 is fabricated from a zinc and aluminum metal alloy, a gas mixture including argon, oxygen may be used to provide oxygen ions, when dissociated, to react with the zinc and aluminum ions sputtered from the target, forming zinc oxide layer having desired concentration of aluminum oxide on the substrate. In the embodiment wherein the selected target 120 is fabricated from zinc oxide and aluminum oxide, a gas mixture including argon gas may be used. The oxygen gas may be optionally supply in the gas mixture. The hydrogen gas may be optionally supplied in both cases.

As discussed above, a TCO layer having a desired amount of Al₂O₃ dopant formed in the ZnO layer may improve the film conductivity and film transparency. The Al₂O₃ dopant source may be provided from the target during processing. In one embodiment, the ratio of Al₂O₃ included in the ZnO target is controlled at between about less than 3 percent, for example about less than 2 percent by weight, such as about less than 0.5 percent by weight, for example, about 0.25 percent by weight. In one embodiment, the lower the dopant concentration of Al₂O₃ formed in the ZnO target, a relatively higher amount of oxygen gas may be supplied in the gas mixture during sputtering to maintain a desired transmittance formed in the TCO layer. For example, if the ratio of Al₂O₃ doped in the ZnO target is about 0.5 percent by weight, the gas mixture may have an oxygen gas flow rate about 5 percent by volume and argon gas flow rate about 95 percent by volume. However, if the ratio of Al₂O₃ doped in the ZnO target is as low as about 0.25 percent by weight, the gas mixture may have a higher oxygen gas flow rate about 7-8 percent by volume and lower argon gas flow rate about 92-93 percent by volume. Since both oxygen elements and Al₂O₃ elements formed in the TCO layer are believed to increase film transmittance, when a lower dopant concentration of Al₂O₃ target is used, a higher oxygen gas in the gas mixture may be used to compensate the lower dopant concentration of Al₂O₃ formed in the target. In some embodiments, hydrogen gas may also be utilized to increase the resultant film transmittance.

In one embodiment, the TCO layer has an Al₂O₃ dopant concentration between about 0.25 percent and about 3 percent in a ZnO based layer.

In operation, the incident light 222 provided by the environment is supplied to the PV solar cell 200. The photoelectric conversion unit 214 in the PV solar cell 200 absorbs the light energy and converts the light energy into electrical energy by operation of the p-i-n junctions formed in the photoelectric conversion unit 214, thereby generating electricity or energy. Alternatively, the PV solar cell 200 may be fabricated or deposited in a reversed order. For example, the substrate 114 may be disposed over the back reflector 216.

FIG. 4 depicts an exemplary cross sectional view of a tandem type PV solar cell 400 fabricated in accordance with another embodiment of the present invention. Tandem type PV solar cell 400 has a similar structure of the PV solar cell 200 including a bottom TCO layer 402 formed on the substrate 114 and a first photoelectric conversion unit 422 formed on the TCO layer 402. The first photoelectric conversion unit 422 may be μc-Si based, poly-silicon or amorphous based photoelectric conversion unit as described with reference to the photoelectric conversion unit 214 of FIG. 2. An intermediate layer 410 may be formed between the first photoelectric conversion unit 422 and a second photoelectric conversion unit 424. The intermediate layer 410 may be a TCO layer sputter deposited by the process 300 described above. Alternatively, the intermediate layer 410 may be a SiO, SiC, SiON, or other suitable doped silicon alloy layer. The combination of the first underlying conversion unit 422 and the second photoelectric conversion unit 424 as depicted in FIG. 4 increases the overall photoelectric conversion efficiency.

The second photoelectric conversion unit 424 may be μc-Si based, polysilicon or amorphous based, and have an μc-Si film as the i-type semiconductor layer 414 sandwiched between a p-type semiconductor layer 412 and a n-type semiconductor layer 416. A back reflector 426 is disposed on the second photoelectric conversion unit 424. The back reflector 426 may be similar to back reflector 216 as described with reference to FIG. 2. The back reflector 426 may comprise a conductive layer 420 formed on a top TCO layer 418. The materials of the conductive layer 420 and the TCO layer 418 may be similar to the conductive layer 212 and TCO layer 210 as described with reference to FIG. 2.

Thus, methods for sputtering depositing a TCO layer with high transmittance are provided. The method advantageously produces a TCO layer having desired optical film properties across its thickness. In this manner, the TCO layers efficiently increase the photoelectric conversion efficiency and device performance of the PV solar cell as compared to conventional methods.

While the foregoing is directed to embodiments of the present invention, other and further embodiments of the invention may be devised without departing from the basic scope thereof, and the scope thereof is determined by the claims that follow.

What is claimed is:

1. A method of sputter depositing a transparent conductive layer, comprising:
supplying a gas mixture into a processing chamber;
sputtering a source material from a target disposed in the processing chamber, wherein the target is fabricated from a zinc containing material having an aluminum containing dopant concentration less than 3 percent by weight; and
reacting the sputtered material with the gas mixture to deposit a transparent conductive layer on a substrate.

2. The method of claim 1, wherein supplying the gas mixture further comprises:
supplying a gas mixture selected from a group consisting of O₂, N₂, Ar, He and H₂ to the process chamber.

3. The method of claim 1, wherein the gas mixture includes at least one of O₂, H₂ and Ar.

4. The method of claim 1, wherein the gas mixture includes oxygen gas and an argon gas, wherein the oxygen gas is supplied less than 10 percent by volume in the gas mixture and the argon gas is supplied between about 90 and about 100 percent by volume in the gas mixture.

5. The method of claim 4, further comprising:
supplying oxygen gas at a flow rate between about 0 sccm and about 100 sccm; and
supplying argon gas at a flow rate between about 150 sccm and about 500 sccm.

6. The method of claim 1, wherein the gas mixture includes oxygen gas, a hydrogen gas, and an argon gas, wherein the oxygen gas is supplied less than 10 percent by volume in the gas mixture, and the hydrogen gas is supplied at less than 10 percent by volume in the gas mixture, and the argon gas is supplied between about 80 and about 100 percent in the gas mixture.

7. The method of claim 6, further comprising:
supplying O₂ gas at a flow rate between about 0 sccm and about 100 sccm;
supplying H₂ gas at a flow rate between about 0 sccm and about 100 sccm; and
supplying Ar gas at a flow rate between about 100 sccm and about 500 sccm.

8. The method of claim 1, wherein the aluminum containing dopant formed in the target includes at least one of aluminum alloy or aluminum oxide, and the zinc containing material includes at least one of zinc alloy or zinc oxide.

9. The method of claim 1, wherein the aluminum containing dopant concentration of the target is about 0.25 percent by weight.

10. The method of claim 1, wherein sputtering source material from the target further comprises:
applying a RF power between about 1000 Watts and about 60000 Watts to the target.

11. The method of claim 1 further comprising:
depositing a photoelectric conversion unit over the transparent conductive layer.

12. A method of sputter depositing a transparent conductive layer, comprising:
providing a substrate in a processing chamber;
supplying a gas mixture into the processing chamber;
sputtering source material from a target disposed in the processing chamber;
reacting the sputtered material with the gas mixture; and
forming a transparent conductive layer on the substrate from the reacted sputtered material, wherein the transparent conductive layer is a zinc oxide layer having an aluminum oxide dopant concentration between about 0.25 percent by weight and about 3 percent by weight.

13. The method of claim 12, wherein the target is fabricated from a zinc containing material having an aluminum containing dopant concentration less than about 3 percent by weight.

14. The method of claim 12, wherein gas mixture includes at least one of O₂, H₂ and Ar.

15. The method of claim 12, wherein the gas mixture includes an oxygen gas and an argon gas, wherein the oxygen gas is supplied less than 10 percent in the gas mixture and the argon gas is supplied between about 90 and about 100 percent in the gas mixture.

16. The method of claim 12, wherein the gas mixture includes an oxygen gas, a hydrogen gas, and an argon gas, wherein the oxygen gas is supplied at less than 10 percent by volume in the gas mixture, and the hydrogen gas is supplied at less than 10 percent by volume in the gas mixture, and the argon gas is supplied at between about 80 and about 100 percent in the gas mixture.

17. The method of claim 12, wherein sputtering source material from the target further comprises:
applying a RF power between about 1000 Watts and about 60000 Watts to the target.

18. A method of sputter depositing a transparent conductive layer, comprising:
providing a substrate in a processing chamber;
supplying a gas mixture comprising at least an argon gas and an oxygen gas into the processing chamber;
sputtering source material from a target fabricated from a zinc oxide material having an aluminum oxide dopant less than 3 percent by weight disposed in the processing chamber; and
reacting the sputtered source material with the gas mixture to form a transparent conductive layer on the substrate.

19. The method of claim 18, wherein the transparent conductive layer is a ZnO layer having an Al₂O₃ dopant concentration between about 0.25 percent by weight and about 3 percent by weight.

20. The method of claim 18, wherein the oxygen gas is supplied at less than 10 percent in the gas mixture and the argon gas is supplied at between about 90 and about 100 percent in the gas mixture.

21. The method of claim 18, wherein the gas mixture further comprises a hydrogen gas.

22. The method of claim 21, wherein the oxygen gas is supplied at less than 10 percent by volume in the gas mixture, and the hydrogen gas is supplied at less than 10 percent by volume in the gas mixture, and the argon gas is supplied at between about 80 and about 100 percent in the gas mixture.

23. A method of sputter depositing a transparent conductive layer, comprising:
providing a substrate in a processing chamber;
supplying a gas mixture comprising at least an argon gas and an oxygen gas into the processing chamber;
sputtering source material from a target fabricated from a zinc oxide material having an aluminum oxide dopant less than 3 percent by weight disposed in the processing chamber; and
reacting the sputtered source material with the gas mixture to form a transparent conductive layer on the substrate, wherein the transparent conductive layer is a ZnO layer having an Al₂O₃ dopant concentration between about 0.25 percent by weight and about 3 percent by weight.
